(19) United States
(12) Patent Application Publication
(10) Pub. No.: US 2006/0121211 A1
(43) Pub. Date: Jun. 8, 2006

(54) Chemical vapor deposition apparatus and chemical vapor deposition method using the same

(76) Inventor: Byung-Chul Choi, Suwon-si (KR)

Correspondence Address: VOLENTINE FRANCOS, & WHITT PLLC, ONE FREEDOM SQUARE, 11951 FREEDOM DRIVE SUITE 1260, RESTON, VA, 20190, US

(21) Appl. No.: 11/294,429

(22) Filed: Dec. 6, 2005

(30) Foreign Application Priority Data
Dec. 7, 2004 (KR) 2004-102290

(51) Int. Cl. C23C 16/00; H05H 1/24

(52) U.S. Cl. 427/569; 118/715; 427/248.1

(57) ABSTRACT

chemical vapor deposition (CVD) equipment and a CVD method using the same enhance production yield by preventing non-reacted gas from agglomerating on a substrate before the plasma reaction is induced. This source gas is composed of first and second gases. Only the first gas is initially supplied into the process chamber of the CVD equipment. Then the second source gas and the first source gas are supplied as a mixture but at this time are dumped to the exhaust section of the CVD equipment so as to bypass the process chamber. After a delay, the first source gas and the second source gas are supplied together as source gas into the process chamber and at this time, an RF power is applied to the source gas to induce the plasma reaction that forms a film on a wafer disposed inside the chamber. Thus, non-reacted gas is prevented from agglomerating on the substrate. As a result, the film has a high degree of uniformity.

### BACKGROUND OF THE INVENTION

1. Field of the Invention

The present invention relates to semiconductor fabrication equipment. More particularly, the present invention relates to chemical vapor deposition (CVD) equipment and to a CVD method using the same for forming a thin film on a wafer or the like.

2. Description of the Related Art

Recently, the line widths of the integrated circuits of semiconductor chips are gradually being reduced to increase the speed at which the semiconductor chips operate and to increase the storage capacity per unit area of the chips. Furthermore, semiconductor devices themselves, such as the transistors integrated on a semiconductor wafer, have been scaled down to dimensions on the order of a half micron or less.

The processes used to fabricate a semiconductor device include a deposition process, a photolithography process, an etch process, and a diffusion process. These processes are repeatedly performed several or tens of times on a wafer to fabricate at least one semiconductor device. In particular, the deposition process is performed to form a thin film on a wafer, and the reproducibility of the deposition process is thus essential in fabricating reliable semiconductor devices. Such a deposition process may be performed using a sol-gel method, a sputtering method, an electro-plating method, an evaporation method, a chemical vapor deposition (CVD) method, a molecular beam epitaxy (MBE) method, or an atomic layer deposition (ALD) method.

The CVD method is most widely used because of its ability to form a thin film on a wafer that is much more uniform than those which can be formed by other deposition methods. The CVD method may be classified, according to a processing condition under which the method is carried out, as low pressure chemical vapor deposition (LPCVD), atmospheric pressure chemical vapor deposition (APCVD), low temperature chemical vapor deposition (LTCVD), or plasma enhanced chemical vapor deposition (PECVD).

For example, PECVD is a method used to form a dielectric layer on a wafer. In PECVD, a chemical reaction of gases is produced via an electric discharge. A product of the chemical reaction is a deposited on the wafer. In a conventional PECVD process, a plurality of wafers are loaded into a processing chamber of a plasma CVD apparatus, and layers are respectively formed all at once on the wafers by PECVD. Recently, however, the diameter of a typical wafer has become quite large, and the semiconductor devices to be formed thereon are to be highly-integrated. Accordingly, in a recent PECVD method, only one wafer at a time is loaded into the processing chamber of the plasma CVD apparatus, and a PECVD process is performed on the wafer. Then, a cleaning and purging process is performed to remove gases remaining inside the processing chamber of the plasma CVD apparatus and to remove a by-product of the chemical reaction from surfaces inside the processing chamber.

One example of CVD equipment for forming an interlayer insulating layer, such as a silicon oxide layer, on a wafer is disclosed in U.S. Pat. No. 6,009,827. Such conventional CVD equipment and a conventional CVD method using the same will be described below with reference to FIGS. 1 and 2.

Referring first to FIG. 1, the conventional CVD equipment includes a source gas supply section 10 that provides a supply of source gas, a purge gas supply section 40 that provides a source of purge gas, a process chamber 20 in which a thin film is formed on a wafer, a supply line 12 connecting the source gas supply section 10 and the purge gas supply section 40 to the chamber 20, and an exhaust section 30 for evacuating the process chamber 20. The source gas supply section 10 includes an oxygen gas tank 15a for storing oxygen, a TEOS gas tank for storing TEOS gas, a first flow control valve 16a and a second flow control valve 16b for controlling the flow rates of the oxygen gas and the TEOS gas from the oxygen gas and TEOS gas tanks, respectively, and a first shutoff valve 18a and a second shutoff valve 18b that can be opened and closed to selectively supply the oxygen gas and the TEOS gas into the process chamber 20 via the supply line 12. Similarly, the purge gas supply section 40 includes a purge gas tank for storing a purge gas, a third flow control valve 16c for controlling the flow rate of the purge gas from the purge gas tank, and a third shut off valve 18c that can be opened and closed to selectively supply the purge gas into the process chamber 20 via the supply line 12.

Furthermore, the CVD equipment includes a chuck 24 disposed at the bottom of the process chamber 20, a shower head 28 disposed at the top of the process chamber 20 opposite the chuck 24, and at least one plasma electrode 26 disposed over the shower head 28 (electrode 26a) or below the chuck 24 (electrode 26b). The wafer 22 on which the thin film is to be formed is supported and fixed in place by the chuck 24. The shower head 26 receives gas from the supply line 12 and sprays the gas, e.g., the oxygen gas and the TEOS gas, uniformly over the wafer 22. The at least one electrode 26a, 26b induces a reaction in a high-temperature state between the oxygen gas and the TEOS gas. To this end, an external power source applies an RF power to the at least one plasma electrode 26a, 26b. As a result, a silicon oxide layer having a high degree of uniformity is formed on the wafer 22.

The exhaust section 30 includes an exhaust line 32 communicating with the process chamber 20a, a vacuum pump system 34 connected to the exhaust line 32 for pumping air/gas from the process chamber 20, and a pressure control valve 36 disposed in the exhaust line 32 for controlling the amount of air pumped by the vacuum pump system 34 from the chamber 20 to maintain a vacuum inside the process chamber 20.

More specifically, the vacuum pump system 34 gradually pumps the air out of the process chamber 20. The system 34 includes a high vacuum pump 34a such as a turbo pump or a diffusion pump and a low vacuum pump 34b connected in series in the exhaust line 32 downstream of the pressure control valve 36. Also, a dummy exhaust line 32a branches from the exhaust line 32 at a location between the pressure control valve 36 and the high vacuum pump 34a, and rejoins the exhaust line 32 downstream of the high vacuum pump 34a. A luffing valve 38a is disposed in the dummy exhaust line 32a. A fore line valve 38 is disposed in the exhaust line 32 between the high vacuum pump 34a and the fore (upstream) end of the low vacuum pump 34b. The exhaust section 30 further includes a scrubber (not shown) for purifying the gas exhausted from the chamber 20 before the gas is vented to the atmosphere.

A CVD method using the conventional CVD equipment having the structure described above will be explained with reference to FIG. 2.

The conventional CVD method includes loading the wafer 22 into the process chamber 20, and pumping air from inside the process chamber 20 to create a vacuum in the chamber 20 (s10). At this time, the air inside the process chamber 20 is in a higher vacuum state than that prevailing during the subsequent deposition process. That is, the air is pumped from the process chamber 20 at a relatively high rate to remove foreign contaminants from the process chamber 20 while the wafer 22 is being loaded into the chamber 20.

Then, oxygen gas is supplied into the process chamber 20 at a predetermined flow rate (s20). At this time, a low vacuum state is maintained in the process chamber 20.

Then, TEOS gas is supplied into the process chamber 20 along with the oxygen gas at a predetermined flow rate (s30). Hence, the oxygen gas and the TEOS gas are mixed and flow over the wafer 22. At this time, however, the oxygen gas and the TEOS gas cannot react uniformly because they are at room temperature. That is, the oxygen gas and the TEOS gas do not chemically react uniformly until a plasma is induced. Therefore, non-reacted TEOS gas agglomerates on the surface of the wafer 22a.

Then, RF power is applied to the plasma electrode 26 while the oxygen gas and the TEOS gas continue to flow into the process chamber 20 to induce a plasma reaction. As a result, a silicon oxide layer is formed on the wafer 22 (s40). In this case, the high temperature causes the oxygen gas and the TEOS gas react uniformly.

Once the silicon oxide layer attains a predetermined thickness, the supplying of the oxygen gas and the TEOS gas into the process chamber 20 is cut off, and the applying of RF power to the plasma electrode 26 is interrupted to extinguish the plasma. Oxygen gas and TEOS gas are then pumped out of the process chamber 20 (s50).

Then, purge gas is supplied into the chamber 20 while the process chamber 20 continues to be evacuated such that all of the oxygen gas and the TEOS gas remaining inside the process chamber 20 are removed from the process chamber (s60). After a period of time, the supplying of the purge gas is then cut off and the purge gas remaining in the process chamber 20 is pumped out of the chamber 20 (s70). The supplying of the purge gas into and the pumping of the purge gas from the chamber 20 can be performed periodically, i.e., can be repeated a number of times.

However, the conventional CVD method described above has the following problem.

The oxygen gas and the TEOS gas flowing over the wafer 22 do not react uniformly before the plasma is induced. Therefore, the non-reacted TEOS gas agglomerates on the wafer. As a result, the silicon oxide layer formed on the wafer 22 is non-uniform. The thickness of the silicon oxide layer can vary so much as to affect the processes which are to be subsequently carried out on the wafer. This failure of the deposition process lowers the overall production yield.

### SUMMARY OF THE INVENTION

Therefore, an object of the present invention is to provide chemical vapor deposition (CVD) equipment and a CVD method using the same by which contribute to increasing or optimizing the production yield.

A more specific object of the present invention is to provide chemical vapor deposition (CVD) equipment and a CVD method using the same, in which the gases that constitute the source gas of the process are not allowed to flow over the substrate before the plasma reaction is induced.

According to one aspect of the present invention, there is provided chemical vapor deposition (CVD) equipment including a source gas supply section, a process chamber in which a thin film is formed on a substrate using source gas from the source gas supply section, a supply line connecting the source gas supply section to the process chamber, an exhaust section by which air/gas is pumped from the process chamber, and a dump line connecting the supply line and the exhaust section and bypassing the process chamber.

According to another aspect of the present invention, there is provided a CVD method including providing supply sources of first and second gases that together constitute the source gas of a CVD process, supplying only the first gas from the source thereof into the process chamber, subsequently supplying the second source gas and the first source gas from the sources thereof directly to an exhaust section by which air/gas is pumped from the chamber so that the gases bypass the process chamber, and then supplying the first source gas and the second source gas into the process chamber and simultaneously inducing a plasma reaction to thereby form a film on a substrate disposed in the chamber.

According to still another aspect of the invention, there is provided a CVD method of forming a silicon oxide layer on a substrate, wherein the first and second gases are oxygen gas and TEOS gas, respectively. In this particular process, the oxygen gas is supplied into the process chamber at a flow rate of about 8000 sccm, the oxygen gas is supplied into the process chamber at a flow rate of about 350 sccm, air/gas is pumped out of the process chamber to maintain a vacuum pressure of about 2.5 Torr in the process chamber during the plasma reaction, and the plasma reaction is induced by exciting the source gas with an RF power of about 300 to 600 W.

### BRIEF DESCRIPTION OF THE DRAWINGS

The above and other objects, features and advantages of the present invention will become more apparent from the following detailed description of the preferred embodiments thereof made with reference to the attached drawings in which:

FIG. 1 is a schematic diagram of conventional chemical vapor deposition (CVD) equipment;

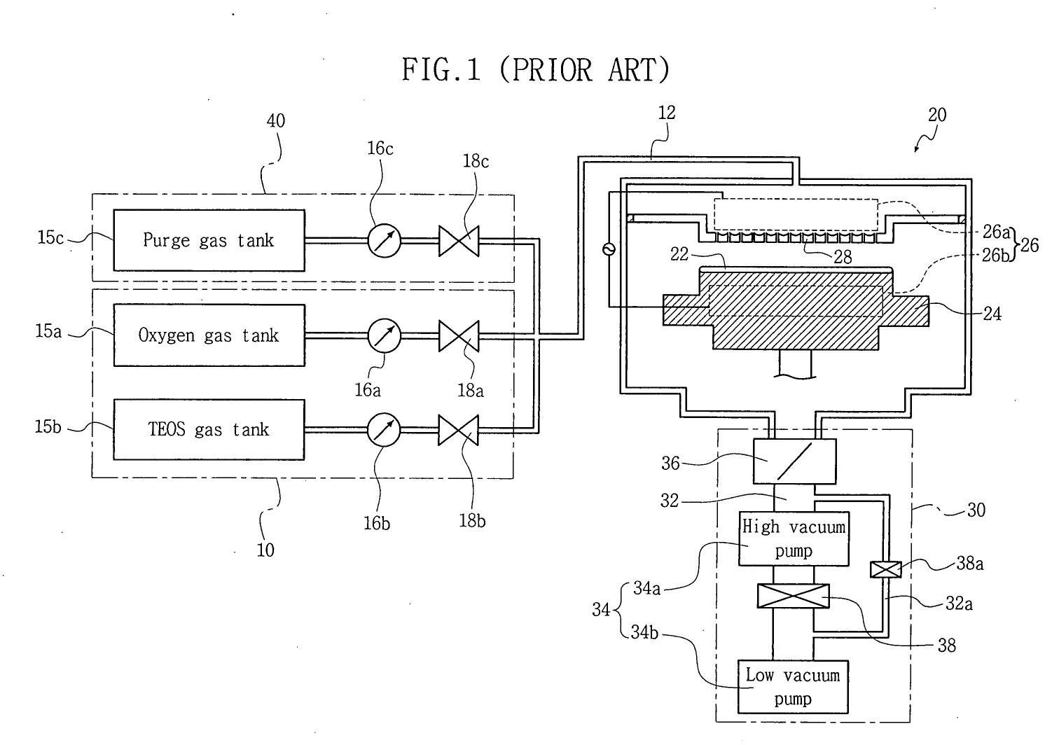

FIG. 2 is a flowchart illustrating a conventional CVD method;

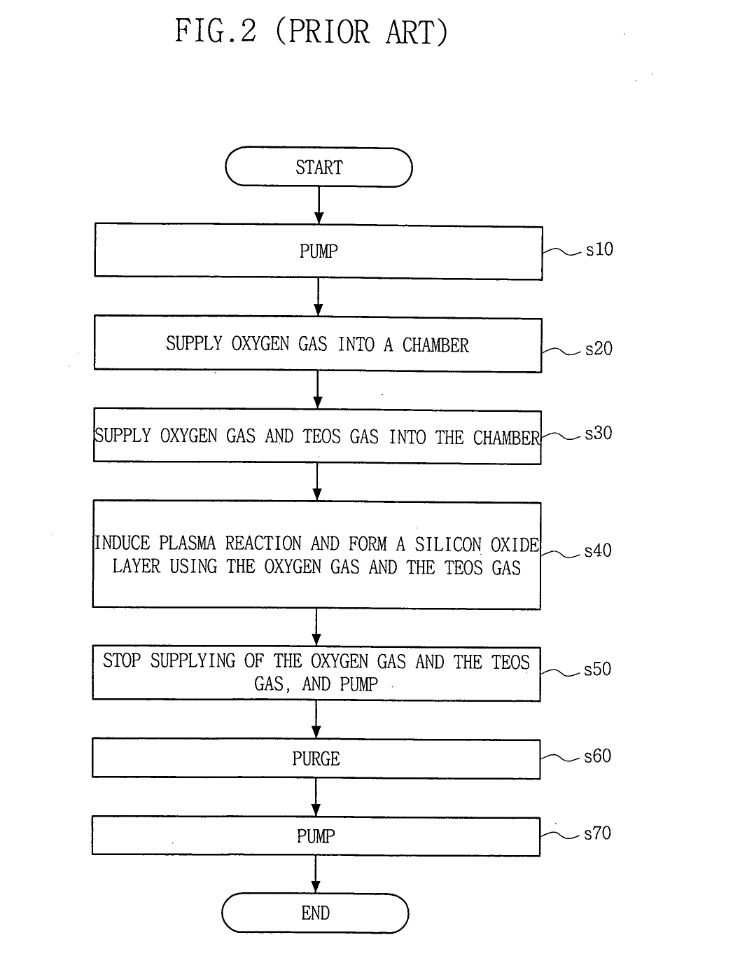

FIG. 3 is a schematic diagram of CVD equipment according to the present invention; and

FIG. 4 is a flow chart illustrating a CVD method according to the present invention.

### DETAILED DESCRIPTION OF THE PREFERRED EMBODIMENTS

The present invention will now be described in more detail with reference to the accompanying drawings.

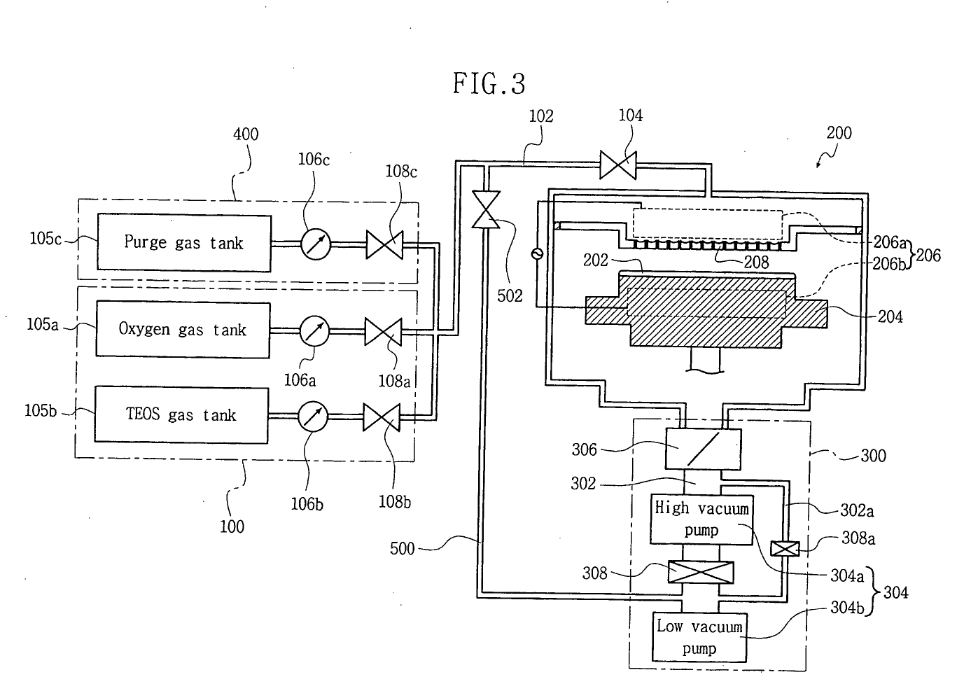

Referring to FIG. 3, the CVD equipment of the present invention includes a source gas supply section 100 providing a supply of source gas, a process chamber 200 in which a plasma reaction is induced using source gas from the source gas supply section 100 to form a thin film on a wafer 202, a supply line 102 connecting the source gas supply section 100 to the process chamber 200, an exhaust section 300 for pumping air/gas out of the process chamber 200, and a dump line 500 connecting the supply line 102 to the exhaust section 300 so that source gas supplied from the source gas supply section 100 can bypass the process chamber 200.

More specifically, the dump line 500 is connected to the supply line 102 between the source gas supply section 100 and the process chamber 200. A first valve 104 is disposed in the supply line 102 between the process chamber 200 and the location at which the dump line 500 is connected to the supply line 102. A second valve 502 is disposed in the dump line 500. The first valve 104 and the second valve 502 can be opened and closed independently of each other. Thus, source gas from the source gas supply section 100 is supplied to the process chamber 200 when the first valve 104 is opened and the second valve 502 is closed. On the contrary, the source gas flows through the dump line 500 to the exhaust section 300, bypassing the process chamber 200, when the first valve 104 is closed and the second valve 502 is opened.

The source gas supply section 100 provides a plurality of gases which will generate a chemical reaction inside the process chamber 200 to form a thin film on a wafer 202, and supplies the gases to the process chamber 200 at a predetermined flow rate. For example, the source gas may be a mixture of oxygen gas (first gas) and TEOS gas (second gas). Thus, the source gas supply section 100 includes an oxygen gas tank 105a and a TEOS gas tank 105b, first and second flow control valves 106a, 106b controlling the rates at which the oxygen gas and the TEOS gas flow from the oxygen and TEOS gas tanks 105a, 105b, respectively, and first and second shutoff valves 108a, 108b that can be opened or closed to selectively supply the oxygen gas and the TEOS gas to the supply line 102. In this embodiment, the sections of the supply line 102 connected to the oxygen gas and TEOS gas tanks 105a, 105b merge into a single line from which the dump line 500 branches.

Furthermore, the CVD equipment of the present invention includes a purge gas supply section 400 for supplying purge gas to the process chamber 200 through the supply line 102. The purge gas supply section 400 includes a purge gas tank 105c, a third flow control valve 106c controlling the rate at which the purge gas flows from the purge gas tank 105c, and a third flow shutoff valve 108c that can be opened or closed to selectively supply the purge gas to the supply line 102.

The CVD equipment of the present invention may include a cleaning gas supply section (not shown) for supplying cleaning gas into the process chamber 200 through the supply line 102. Any cleaning gas remaining in the supply line 102 after the cleaning process can be removed from the supply line 102 via the dump line 500, i.e., without entering the process chamber 200, prior to a subsequent deposition process.

The CVD equipment also includes a shower head 206, a chuck 204, at least one plasma electrode 206, and an external RF power source that applies an RF power to the at least one plasma electrode. The shower head 206 is disposed at the top of the process chamber 200 for uniformly spraying the source gas, such as oxygen gas and TEOS gas, over the wafer. The chuck 204 is disposed at the bottom of the process chamber 200 across from the shower head 206 for supporting the wafer 202 and fixing the wafer 202 in place during the deposition process. The chuck 204 also positions the wafer 202 at a distance of about 1.5 cm from the shower head 206. The at least one plasma electrode 206 includes an electrode 206b disposed below the chuck 204 and/or an electrode 206a disposed over the shower head 202. The at least one electrode 26 induces a high-temperature plasma reaction in the source gas when RF power is applied thereto.

Preferably, the process chamber 200 is part of cluster type processing equipment in which a transfer chamber having a transfer robot is connected to the process chamber 200 for loading the wafer 202 into and unloading the wafer 202 from the process chamber 200. In this type of equipment, the process chamber is maintained at a relatively high pressure during the thin film forming (deposition) process compared to the transfer chamber. Also, a heater fixed to the chuck 204 for heating the wafer 202 to a predetermined temperature, and a pressure gauge is provided for measuring the pressure (level of vacuum) inside the process chamber 200. The pressure gauge may comprise a 1 Torr Baratron sensor (not shown) for measuring relatively low pressures and a 100 Torr Baratron sensor (not shown) for measuring relatively high pressures such that the pressure inside the process chamber 200 is measured in two steps. The pressure gauge may be directly installed inside the process chamber 200, or may be installed in the exhaust line 302 whereby the pressure inside the process chamber 200 is determined according to the pressure of the air that is exhausted from the chamber 204.

The exhaust section 300 includes an exhaust line 302 extending from and communicating with the process chamber 200, a vacuum pump system 304 connected to the exhaust line 302 for pumping air/gas out of the process chamber 200 through the exhaust line 302, and a pressure control valve 306 disposed in the exhausting line 302 for controlling the amount of air/gas pumped from the process chamber 200 by the vacuum pump system 304 to maintain a vacuum, i.e., a certain level of negative pressure, inside the process chamber 200. The vacuum pump system 304 may gradually increase the rate at which the air is pumped from the process chamber 200. To this end, the vacuum pump system 304 includes a high vacuum pump 304a such as a turbo pump or a diffusion pump and a low vacuum pump 304b connected in series in the exhaust line 302 downstream of the pressure control valve 306.

In addition, a dummy exhaust line 302a diverges from the exhaust line 302 at a location between the high vacuum pump 304a and the process chamber 200 and rejoins the exhaust line 302 downstream of the high vacuum pump 304a. A luffing valve 308a is disposed in the dummy exhaust line 302a. A fore line valve 308 is disposed in the exhaust line 302 between the high vacuum pump 304a and the low vacuum pump 304b, i.e., in the section of the exhaust line 302 from which the dummy exhaust line 302a extends. The luffing valve 308a and the fore line valve 308 can be opened and closed independently of each other like the first valve 104 and the second valve 102. The exhaust section 300 further includes a scrubber (not shown) for purifying the air or the gas exhausted through the low vacuum pump 304b before the air/gas is vented to the atmosphere. The dump line 500 is connected to the exhaust line 302 at a fore end (upstream) of the low vacuum pump 304b. Alternatively, the dump line can be connected to the dummy exhaust line between the luffing valve 308a and the low vacuum pump 304b.

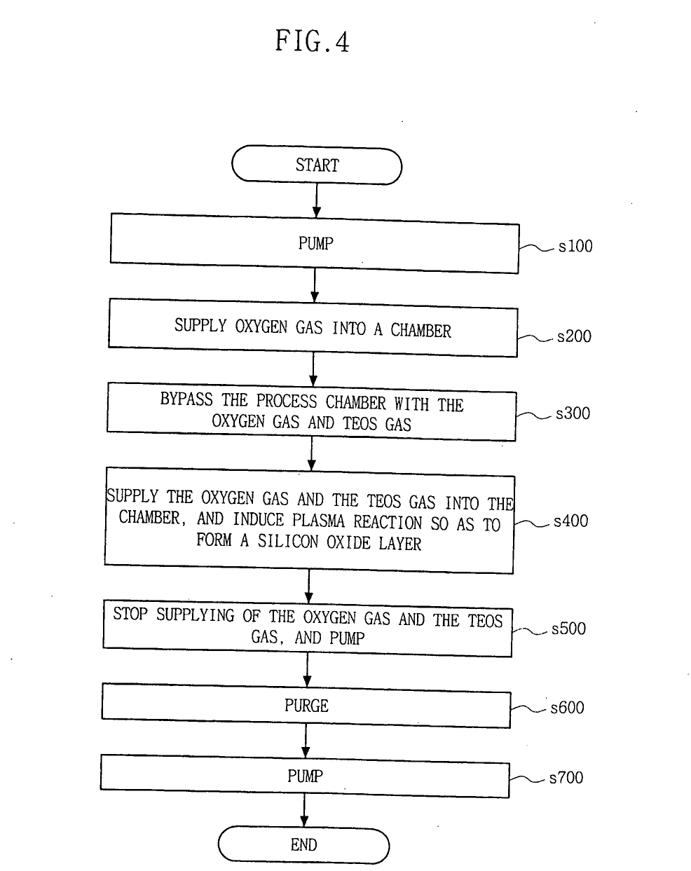

A CVD method according to the present invention using the CVD equipment described above will now be described with additional reference to FIG. 4.

First, a wafer 202 is loaded onto the chuck 204 in the process chamber 200 from a transfer chamber, and a door disposed between the process chamber 200 and the transfer chamber is closed. At this time, air is pumped from the process chamber 200 using the low vacuum pump 304b and the high vacuum pump 304a of the exhaust section 300 (s100). For example, the air is pumped from the process chamber 200 using the low vacuum pump 304b with the luffing valve 308a open until a low level of vacuum of about 10⁻³ Torr is produced in the chamber 200. Then, the luffing valve 308a is closed, the fore line valve 308 is opened, and air is pumped from the process chamber 200 using the high vacuum pump 304a and the low vacuum pump 304b until a high level of vacuum of about 10⁻⁶ Torr is produced in the chamber 200.

Then, oxygen gas is introduced into the process chamber 200 at a predetermined flow rate through the supply line 102 (s200). For example, the oxygen gas is supplied into the process chamber 200 at a flow rate of about 8000 sccm for about 20 seconds. The flow rate of the oxygen gas is controlled by the first flow rate control valve 106a while the first valve 104 is open. At this time, a low level of vacuum is again produced in the process chamber 200 because of the oxygen gas in the process chamber 200.

Furthermore, the luffing valve 308a is closed, the fore line valve 308 is opened, and the low vacuum pump 304b and the high vacuum pump 304a pump air/gas from the process chamber 200 while the oxygen gas is supplied into the process chamber 200 until a vacuum pressure of about 2.5 Torr prevails in the process chamber 200. Alternatively, only the low vacuum pump 304b may be used to pump the air from the process chamber 200 while the luffing valve 308a is closed and the fore line valve 308 is open. In any case, the vacuum pressure inside the process chamber 200 is regulated by the pressure control valve 306.

Next, the TEOS gas is supplied from the source gas supply section 100, and the first valve 104 disposed in the supply line 102 is closed and the second valve 502 disposed in the dump line 502 is opened. Thus, the oxygen gas and the TEOS gas supplied from the source gas supply section 100 bypass the process chamber 200 by flowing to the exhaust section 300 through the dump line 500 for about 15 seconds (s300). At this time, the flow rates of the oxygen gas and the TEOS gas are controlled to be the same as or similar to the rates at which the gases are supplied into the process chamber during the deposition process described below.

For example, the oxygen gas is controlled to flow through the dump line 500 at a rate of about 8000 sccm, and the TEOS gas is controlled to flow through the dump line 500 at a rate of about 350 sccm. During this time, the vacuum pressure inside of the process chamber 200 is maintained at about 2.5 Torr. Furthermore, the wafer 202 is heated on the chuck 204 to a predetermined temperature.

Then, the TEOS gas and the oxygen gas are supplied into the process chamber 200. At the same time, RF power is applied to the plasma electrode 206 to induce a plasma reaction. As a result, a silicon oxide layer is formed on the wafer 202 (s400). As mentioned above, the rates at which the TEOS gas and the oxygen gas are supplied into the process chamber 200 are the same as or similar to those as the rates at which the TEOS gas and the oxygen gas had been flowing through the dump line 500.

For example, the oxygen gas is supplied into the process chamber 200 at a flow rate of about 8000 sccm, and the TEOS gas is supplied into the process chamber 200 at a flow rate of about 350 sccm, both for about 9.4 seconds. Also, an RF power of about 300 to 600 W is applied to the source gas via the plasma electrode 206 to induce a plasma reaction. Still further, the temperature within the process chamber 200 is maintained at about 400° C., and the wafer 202 is also heated by the heater to have a temperature equal to or similar to the temperature in the process chamber 200. The flow rate of gas pumped from the process chamber 200 by the vacuum pump system 304 is regulated by the pressure control valve 306 such that a vacuum pressure of about 2.5 Torr is maintained in the process chamber 200.

Then, the supplying of the TEOS gas and the oxygen gas supplied into the process chamber 200 is cut off, and the plasma reaction is terminated. At this time, TEOS gas and oxygen gas are pumped from the process chamber 200 by the exhaust pump system 304 for a predetermined period of time (s500). For example, the gases are pumped out of the process chamber 200 for about 10 seconds at which time the process chamber has a vacuum pressure of about 0 Torr or less.

Then, purge gas is supplied into the process chamber (s600) through the supply line 102, and any TEOS gas and oxygen gas remaining inside the process chamber 200 is diluted. As an example, nitrogen gas is supplied at a low flow rate for about 20 seconds so that polymer and silicon oxide, formed on the inner wall of the process chamber 200 as a result of the deposition process, will not peel off. Alternatively, the purge gas may be supplied into the process periodically at intervals of about 10 seconds. Moreover, at this time the vacuum pressure in the process chamber is regulated to be about 2.5 Torr.

The air including the purge gas inside the process chamber 200 is exhausted by the vacuum pump system 304 until a predetermined vacuum pressure is produced inside the process chamber (s700). These steps of supplying the purge gas into the process chamber (s600) and pumping the air/gas out of the process chamber (s700) can be performed periodically, i.e., can be repeated a number of times.

Lastly, the door between the process chamber 200 and the transfer chamber is opened, and the robot disposed inside the transfer chamber transfers the wafer 202 from the chuck 204 to the transfer chamber, thereby completing the CVD process.

As described above, according to the present invention, the oxygen gas and the TEOS gas are directed to the exhaust section through the dump line, thereby bypassing the process chamber, before the plasma reaction is induced. Specifically, the oxygen gas and the TEOS gas supplied from the source gas supply section 100 are directed to the exhaust section 300 through the dump line 500 so as to bypass the process chamber 200 as long as RF power is not applied to the plasma electrode 206. Once the RF power is applied to the plasma electrode 206, the oxygen gas and the TEOS gas are supplied into the process chamber 200 and are uniformly mixed, and the plasma reaction is thereby induced to form a uniform silicon oxide layer on the wafer including during the initial stage of the deposition process. That is, the TEOS gas is prevented from agglomerating on the surface of the wafer before the plasma reaction is induced. As a result, a uniform silicon oxide layer is formed by the deposition process, thereby increasing or optimizing a production yield.

Finally, although the present invention has been described in connection with the preferred embodiments thereof, the scope of the invention is not so limited. Rather, various modifications and alternatives are sen to be within the true spirit and scope of the invention as defined by the appended claims.

What is claimed is:

1. Chemical vapor deposition (CVD) equipment comprising:
a process chamber;
a source gas supply section including a supply of source gas used to form a film on a substrate in the process chamber;
a supply line connecting the source gas supply section to the process chamber such that source gas is supplied into the process chamber through the supply line;
an exhaust section including an exhaust line communicating with the process chamber, and a vacuum pump system disposed in the exhaust line such that air/gas can be pumped from the chamber through the exhaust line; and
a dump line connecting the supply line and the exhaust line while by-passing the process chamber, and through which source gas supplied from the source gas supply section can be directed to the exhaust section without passing into the process chamber.

2. The CVD equipment according to claim 1, further comprising:
a chuck disposed at the bottom of the chamber and dedicated to support a substrate;
a shower head disposed at the top of the process chamber and communicating with the supply line so as to spray source gas supplied from the source gas supply section towards the chuck; and
at least one electrode for inducing a plasma reaction of the source gas.

3. The CVD equipment according to claim 1, wherein the exhaust section further comprises a pressure control valve disposed in the exhausting line between the vacuum pump system and the process chamber so as to regulate the amount of air/gas pumped from the process chamber.

4. The CVD equipment according to claim 3, wherein the vacuum pump system comprises a high vacuum pump and a low vacuum pump disposed in series in the exhaust line.

5. The CVD equipment according to claim 4, wherein the high vacuum pump is a turbo pump or a diffusion pump.

6. The CVD equipment according to claim 4, wherein the low vacuum pump is a dry pump.

7. The CVD equipment according to claim 4, wherein the exhaust section further comprises:
a fore line valve disposed in the exhaust line between the high vacuum pump and the low vacuum pump;
a dummy exhaust line diverging from the exhaust line at a location between the pressure control valve and the high vacuum pump, and rejoining the exhaust line at a location between the fore line valve and the low vacuum pump; and
a luffing valve disposed in the dummy exhaust line to cut off the flow of air/gas exhausted through the dummy exhaust line.

8. The CVD equipment according to claim 7, wherein the dump line joins the exhaust section at a location upstream of the low vacuum pump.

9. The CVD equipment according to claim 8, further comprising:
a first valve disposed in the supply line between the location at which the dump line joins the supply line and the process chamber, the first valve being openable and closeable so as to selectively allow and block the flow of source gas from the source gas supply section to the process chamber; and
a second valve disposed in the dump line and being openable and closeable so as to selectively allow and block the flow of source gas from the source gas supply section to the exhaust section via the dump line,
whereby when the first valve is open and the second valve is closed, source gas supplied from the source gas supply section flows to the process chamber through the supply line, and whereby when the first valve is closed and the second valve is open, source gas supplied from the source gas supply section flows to the exhaust section through the dump line while bypassing the process chamber.

10. The CVD equipment according to claim 1, wherein the source gas supply section comprises:
a plurality of gas tanks for containing gases that constitute the source gas;
a plurality of flow control valves through which the gas tanks are connected to the supply line to control the rates at which the source gases flow from the gas tanks, respectively; and
a plurality of shutoff valves through which the gas tanks are connected to the supply line, respectively, the shut off valves each being openable and closable independently of the other so that the gases can be selectively supplied to the supply line from the gas tanks.

11. The CVD equipment according to claim 10, wherein the supply line includes respective line sections connected to the gas tanks via the shutoff valves, respectively, and a single line section into which the respective line sections merge, the dump line joined to the supply line at said single line section.

12. The CVD equipment according to claim 11, further comprising a purge gas supply section including a source of purge gas, the purge gas supply section connected to the supply line upstream of the location at which the dump line joins the supply line.

13. A CVD method comprising:
providing a supply source of a first gas and a supply source of a second gas which together when mixed constitute the source gas of a CVD process;
disposing a substrate within a process chamber;
subsequently supplying the first gas from the source thereof into the process chamber without introducing the second gas into the process chamber;
subsequently supplying the second gas and the first gas from the sources thereof to an exhaust section while bypassing the process chamber, the exhaust section communicating with the process chamber and operative to pump air/gas from the process chamber; and
subsequently supplying the first gas and the second gas into the chamber as source gas, and inducing a plasma reaction of the first and second source gases to form a film on the substrate disposed in the chamber.

14. The method according to claim 13, further comprising pumping air/gas from the process chamber via the exhaust section, before the first gas is supplied into the chamber, to produce a vacuum state in the process chamber.

15. The method according to claim 14, further comprising:
terminating the plasma reaction by cutting off the supplying of the first and second gases into the process chamber, and pumping air/gas from the chamber after the supplying of the first gas and the source gas into the chamber has been cut off;
subsequently supplying purge gas into the chamber; and
terminating the supplying of the purge gas into the chamber; and
subsequently pumping air/gas from the chamber.

16. The method according to claim 15, wherein the supplying of the purge gas into the chamber for a predetermined time, the terminating of the supplying of the purge gas into the chamber, and the subsequent pumping of air/gas from the chamber are sequentially and repeatedly performed a plurality of times.

17. A method of forming a silcon oxide layer on a substrate, comprising:
providing a supply source of oxygen gas and a supply source of TEOS gas;
disposing a substrate within a process chamber;
pumping air/gas from the process chamber to create a vacuum in the process chamber;
subsequently supplying the oxygen gas from the source thereof into the process chamber without introducing the TEOS gas into the process chamber;
while the oxygen gas is being supplied into the process chamber, pumping air/gas out of the chamber through an exhaust line communicating with chamber;
subsequently supplying the TEOS gas and the oxygen gas from the sources thereof to the exhaust line as bypassing the process chamber; and
subsequently supplying the oxygen gas and the TEOS gas into the process chamber as source gas, and concurrently inducing a plasma reaction of the oxygen and TEOS gases in the process chamber to form a film of silicon oxide on the substrate disposed in the chamber.

18. The method according to claim 17, wherein the pumping of air/gas from the process chamber to create a vacuum in the process chamber is carried out to create a vacuum pressure of about 10⁻⁶ Torr at the time the oxygen gas is supplied into the chamber.

19. The method according to claim 18, wherein air/gas is pumped out of the chamber through the exhaust line while the TEOS gas and the oxygen gas bypass the chamber to produce a vacuum pressure of about 2.5 Torr in the chamber at the time the oxygen gas and the TEOS gas are supplied into the chamber.

20. The method according to claim 19, wherein air/gas is pumped out of the process chamber through the exhaust line during the plasma reaction to maintain a vacuum pressure of about 2.5 Torr in the process chamber.

21. The method according to claim 17, wherein the TEOS gas is supplied from the source thereof into the process chamber at a flow rate of about 8000 sccm, the oxygen gas is supplied from the source thereof into the process chamber at a flow rate of about 350 sccm, wherein air/gas is pumped out of the process chamber through the exhaust line during the plasma reaction to maintain a vacuum pressure of about 2.5 Torr in the process chamber, and the plasma reaction is induced by exciting the source gas with an RF power of about 300 to 600 W.
